(19) United States
(12) Patent Application Publication
(10) Pub. No.: US 2026/0110722 A1
(43) Pub. Date: Apr. 23, 2026

(54) AUTOMATIC INSPECTION DEVICE

(71) Applicant: TOYOTA JIDOSHA KABUSHIKI KAISHA, Toyota-shi (JP)

(72) Inventor: Naoki TSUDA, Toyota-shi (JP)

(73) Assignee: TOYOTA JIDOSHA KABUSHIKI KAISHA, Toyota-shi (JP)

(21) Appl. No.: 19/358,851

(22) Filed: Oct. 15, 2025

(30) Foreign Application Priority Data
Oct. 21, 2024 (JP) 2024-185126

(51) Int. Cl. G01R 31/00; G01R 31/28

(52) U.S. Cl. CPC G01R 31/007; G01R 31/2839; G01R 31/2848

(57) ABSTRACT

An automatic inspection device includes: a simulated load; an electronic load; a simulation circuit; and an inspection unit, in which the simulation circuit simulates a disconnection of the simulated load by disconnecting a connection between a power supply system and the electronic load, a connection between an ECU and the electronic load, and a connection between the ECU and the simulated load, simulates a short-circuit of the simulated load by disconnecting the connection between the power supply system and the electronic load, and the connection between the ECU and the simulated load, and conducting the connection between the ECU and the electronic load, and simulates a failure of the power supply system by conducting the connection between the ECU and the simulated load, and the connection between the power supply system and the electronic load, and disconnecting the connection between the ECU and the electronic load.

### CROSS-REFERENCE TO RELATED APPLICATION

This application claims priority to Japanese Patent Application No. 2024-185126 filed on Oct. 21, 2024. The disclosure of the above-identified application, including the specification, drawings, and claims, is incorporated by reference herein in its entirety.

### BACKGROUND

### 1. Technical Field

The present disclosure relates to an automatic inspection device that automatically inspects a power supply control ECU mounted on a vehicle.

### 2. Description of Related Art

Japanese Unexamined Patent Application Publication No. 2008-261793 (JP 2008-261793 A) discloses an automatic inspection device that simulates a state in which a wiring that connects various electronic control units (ECUs) and loads (an engine, a motor, a battery, and the like) mounted on a vehicle is disconnected and automatically inspects operations of the electronic control units in a simulated disconnection state.

### SUMMARY

In the automatic inspection device disclosed in JP 2008-261793 A, an abnormal state in which a connection line between the electronic control unit and the in-vehicle loads is disconnected can be simulated; however an abnormal state, such as a short circuit of the connection line or a failure of a power supply system, cannot be inspected in a simulating manner.

The present disclosure is made in view of such circumstances and is to provide an automatic inspection device capable of simulating an abnormal state, such as a short circuit of a connection line or a failure of a power supply system, in addition to a disconnection of a connection line between an electronic control unit and an in-vehicle load to inspect the electronic control unit.

In order to solve the above problem, an aspect of the technique of the present disclosure provides an automatic inspection device configured to automatically perform inspection of a power supply control ECU, the automatic inspection device including: a simulated load configured to simulate a control target;
an electronic load configured to consume electric power supplied from the power supply control ECU and a power supply system connected to the power supply control ECU that is able to supply electric power;
a simulation circuit disposed between the power supply control ECU and the simulated load, and between the power supply system and the electronic load; and
an inspection unit configured to inspect operation of the power supply control ECU in each of simulation states set by the simulation circuit,
in which the simulation circuit
simulates a disconnection state of the simulated load by disconnecting a connection between the power supply system and the electronic load, a connection between the power supply control ECU and the electronic load, and a connection between the power supply control ECU and the simulated load,
simulates a short-circuit state of the simulated load by disconnecting the connection between the power supply system and the electronic load, and the connection between the power supply control ECU and the simulated load, and conducting the connection between the power supply control ECU and the electronic load, and
simulates a failure state of the power supply system by conducting the connection between the power supply control ECU and the simulated load, and the connection between the power supply system and the electronic load, and disconnecting the connection between the power supply control ECU and the electronic load.

With the automatic inspection device of the present disclosure, an abnormal state, such as a short circuit of a connection line or a failure of a power supply system, can be simulated, in addition to a disconnection of a connection line between an electronic control unit and an in-vehicle load to inspect the electronic control unit.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic diagram of a system configuration including an automatic inspection device according to an embodiment of the present disclosure and peripheral units thereof;

FIG. 2 is a diagram showing a connection state of each of switches of a simulation circuit in a disconnection simulation state;

FIG. 3 is a diagram showing a connection state of each of switches of a simulation circuit in a short-circuit simulation state;

FIG. 4 is a diagram showing a connection state of each of switches of a simulation circuit in a power supply system failure simulation state-1; and

FIG. 5 is a diagram showing a connection state of each of switches of a simulation circuit in a power supply system failure simulation state-2.

### DETAILED DESCRIPTION OF EMBODIMENTS

The automatic inspection device of the present disclosure inspects the electronic control unit by simulating the abnormal state, such as a disconnection of the connection line between the electronic control unit and the in-vehicle load, a short circuit of the connection line, or a failure of the power supply system, in addition to the disconnection of the connection line, by suitably controlling the characteristic simulation circuit and the electronic load.

Hereinafter, an embodiment of the present disclosure will be described in detail with reference to the drawings.

### EMBODIMENT

### Configuration

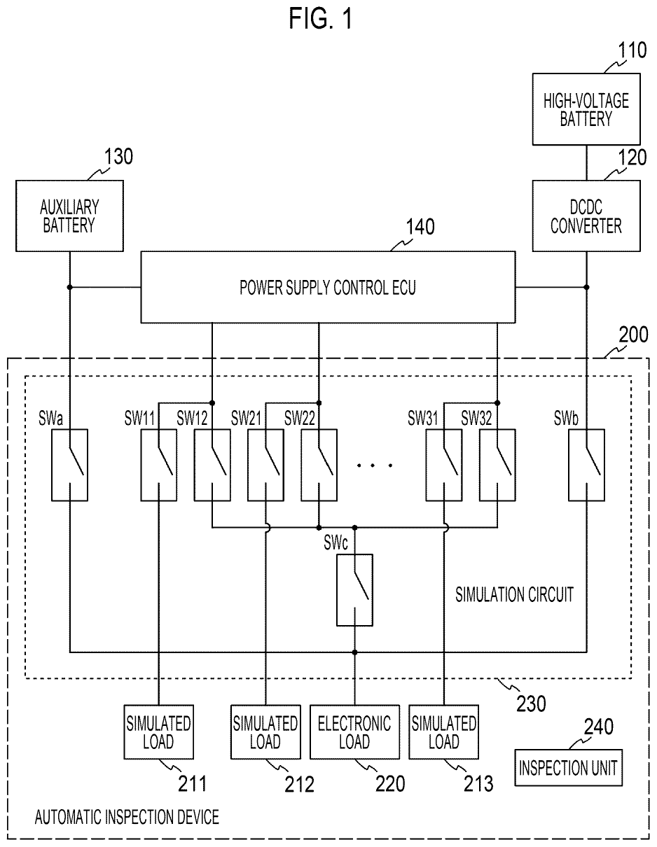

FIG. 1 is a schematic diagram of a system configuration example including an automatic inspection device 200 according to the embodiment of the present disclosure and peripheral units thereof. The system illustrated in FIG. 1 includes a high-voltage battery 110, a DCDC converter 120, an auxiliary battery 130, a power supply control ECU 140, and an automatic inspection device 200. The high-voltage battery 110, the DCDC converter 120, the auxiliary battery 130, and the power supply control ECU 140 are mounted on the vehicle.

The high-voltage battery 110 is a secondary battery configured to be chargeable and dischargeable, such as a lithium ion battery. The high-voltage battery 110 can supply the electric power stored in the high-voltage battery 110 to the power supply control ECU 140 via the DCDC converter 120.

The DCDC converter 120 is provided between the high-voltage battery 110 and the power supply control ECU 140, converts the input voltage of the high-voltage battery 110 into a needed voltage, and is a voltage converter for outputting the converted voltage to the power supply control ECU 140.

The auxiliary battery 130 is a secondary battery configured to be chargeable and dischargeable, such as a lithium ion battery. The auxiliary battery 130 can supply the electric power stored in the auxiliary battery 130 to the power supply control ECU 140.

The power supply control ECU 140 is configured to supply and control electric power to a plurality of loads, such as a large number of devices and equipment mounted on the vehicle, using the high-voltage battery 110 and the auxiliary battery 130 as electric power sources. The power supply control ECU 140 performs complex power supply and control according to various vehicle states, and has control logic for appropriately maintaining the vehicle state when an abnormality such as disconnection or short circuit occurs in the power supply path.

The automatic inspection device 200 simulates an abnormality that may occur in a plurality of loads connected to the power supply control ECU 140 in an actual vehicle and an abnormality that may occur in the high-voltage battery 110 and the auxiliary battery 130 that are electric power sources. The automatic inspection device 200 is configured to inspect whether the power supply control ECU 140 is performing a correct (as designed) operation during an abnormality. The automatic inspection device 200 includes a plurality of simulated loads 211, 212, 213, an electronic load 220, a simulation circuit 230, and an inspection unit 240.

The simulated loads 211, 212, 213 are circuits that respectively simulate actual loads, such as equipment and devices to be controlled mounted on the vehicle. More specifically, the actual loads to be controlled are loads that receive electric power supply from the power supply control ECU 140. The simulated loads 211, 212, 213 are each configured by a resistance value equivalent to a resistance value of the actual load during the steady state. In addition, each of the simulated loads 211, 212, 213 can automatically measure its own power consumption. The number of the simulated loads is not limited to the number shown in FIG. 1, and can be optionally set according to the state of the vehicle to be inspected (inspection state, inspection pattern).

The electronic load 220 is configured to consume the input power. More specifically, the electronic load 220 is connected through a simulation circuit 230 described below and consumes the power input (supplied) from the power supply control ECU 140, the auxiliary battery 130, and the DCDC converter 120. When the power consumption is performed, the electronic load 220 operates to absorb all the electric power input by the maximum consumption current in principle, and operates to gradually absorb the power input by gradually changing the consumption current in an exceptional case.

The simulation circuit 230 is disposed between the power supply control ECU 140, the simulated loads 211, 212, 213, the auxiliary battery 130 and the DCDC converter 120 that configure the power supply system, and the electronic load 220, and is configured to switch between the electrical conduction state and the disconnection state between them.

More specifically, in the simulation circuit 230, the switch SW11 is disposed between the simulated load 211 and the electronic load 220, and the switches SW12, SWc are disposed between the power supply control ECU 140 and the electronic load 220 in parallel to the switch SW11. Similarly, a switch SW21 is disposed between the simulated load 212 and the electronic load 220, and switches SW22, SWc are disposed between the power supply control ECU 140 and the electronic load 220 in parallel to the switch SW21. Similarly, a switch SW31 is disposed between the simulated load 213 and the electronic load 220, and switches SW32, SWc are disposed between the power supply control ECU 140 and the electronic load 220 in parallel to the switch SW31. In addition, a switch SWa is disposed between the auxiliary battery 130 and the electronic load 220, and a switch SWb is disposed between the DCDC converter 120 and the electronic load 220. For the switches SW11, SW12, SW21, SW22, SW31, SW32, SWa, SWb, SWc, for example, a mechanical relay or a semiconductor relay is used.

The inspection unit 240 is a configuration for inspecting the operation of the power supply control ECU 140. In the inspection, the inspection unit 240 controls the electrical conduction and disconnection states of each of the switches SW11, SW12, SW21, SW22, SW31, SW32, SWa, SWb, and SWc in the simulation circuit 230. In addition, the inspection unit 240 controls the operation of the electronic load 220. The inspection unit 240 gives information (pattern) that simulates various vehicle states to the power supply control ECU 140, controls the simulation circuit 230 and the electronic load 220, and measures the output from the power supply control ECU 140 to the simulated loads 211, 212, 213. As a result, the inspection unit 240 can confirm the operation (behavior) of the power supply control ECU 140.

The inspection unit 240 is configured to include, for example, a hardware in the loop simulation (HILS) device including a functional unit that measures a voltage, a current, or the like and a plant model of a load or a sensor, and a personal computer (host PC) for HILS.

### Control

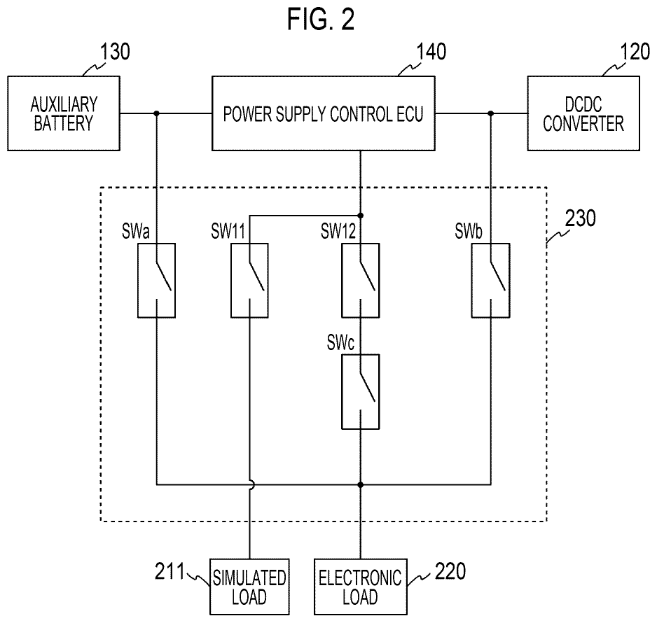

Next, a method of controlling a state of a vehicle to be inspected by the automatic inspection device 200 according to the embodiment of the present disclosure will be described with further reference to FIGS. 2, 3, 4, and 5. In the following description, the abnormality occurring in the simulated load 211 will be described as a representative example of the simulated loads 211, 212, 213.

### (1) Disconnection Simulation State

FIG. 2 is a diagram showing a connection state of switches SW11, SW12, SWa, SWb, SWc in the simulation circuit 230 in a case where a state in which an abnormality of disconnection occurs in a connection line between the power supply control ECU 140 and the simulated load 211 is simulated.

In the disconnection simulation state, all of the switches SW11, SW12, SWa, SWb, SWc in the simulation circuit 230 are controlled to be in the disconnection state. With this control, the power supply control ECU 140 cannot supply the power input from the auxiliary battery 130 and the DCDC converter 120 to the simulated load 211. As a result, the inspection unit 240 can safely and automatically inspect the operation (behavior) of the power supply control ECU 140 in the disconnection simulation state.

### (2) Short-Circuit Simulation State

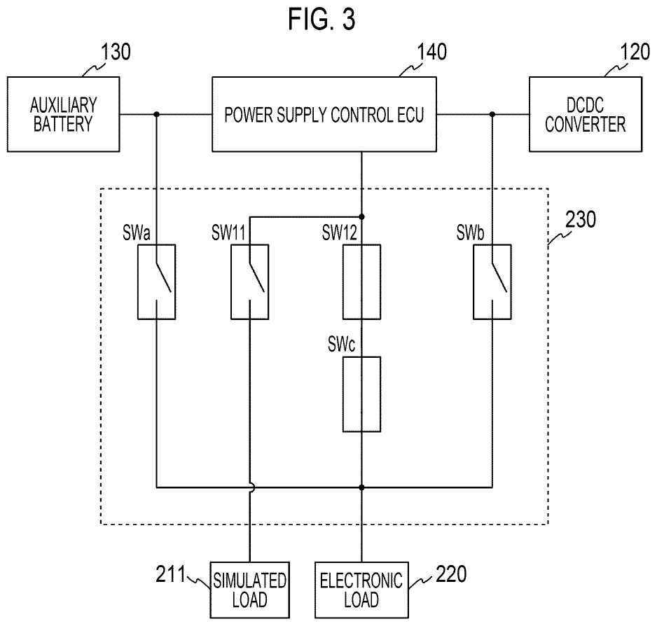

FIG. 3 is a diagram showing a connection state of switches SW11, SW12, SWa, SWb, SWc in the simulation circuit 230 in a case where a state in which an abnormality occurs in which a connection line between the power supply control ECU 140 and the simulated load 211 is shorted to ground level (ground fault) is simulated.

In the short-circuit simulation state, the switches SW11, SWa, and SWb in the simulation circuit 230 are controlled to be in the disconnection state, and the switches SW12 and SWc are controlled to be in the conduction state. With this control, the power supply control ECU 140 consumes all the power input from the auxiliary battery 130 and the DCDC converter 120 in the electronic load 220 without supplying the input electric power to the simulated load 211. As a result, the inspection unit 240 can safely and automatically inspect the operation (behavior) of the power supply control ECU 140 in the short-circuit simulation state.

When a state in which an abnormality occurs in which the connection line between the power supply control ECU 140 and the simulated load 211 is short-circuited (line-to-line fault) to the power supply level is simulated, the electronic load 220 may be controlled to be in an operation state of supplying the voltage of the power supply level.

### (3) Power Supply System Failure Simulation State—1

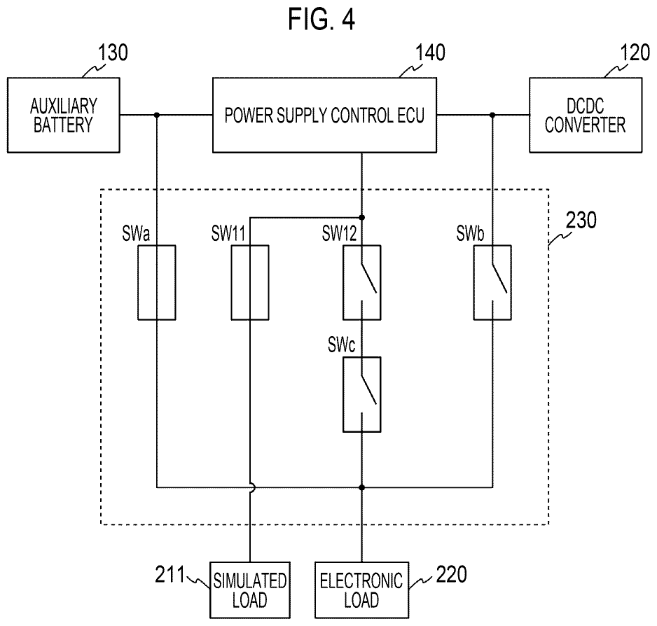

FIG. 4 is a diagram showing a connection state of switches SW11, SW12, SWa, SWb, and SWc in the simulation circuit 230 in a case where a state in which the auxiliary battery 130 fails and an abnormality in which the supply of electric power from the auxiliary battery 130 to the power supply control ECU 140 is lost is simulated.

In the power supply system failure simulation state-1, the switches SW12, SWb, SWc in the simulation circuit 230 are controlled to be in the disconnection state, and the switches SW11, SWa are controlled to be in the conduction state. With this control, all the power output from the auxiliary battery 130 is absorbed by the electronic load 220, and the power supply source from the power supply control ECU 140 to the simulated load 211 is solely the DCDC converter 120. As a result, the inspection unit 240 can safely and automatically inspect the operation (behavior) of the power supply control ECU 140 in the power supply system failure simulation state caused by the auxiliary battery 130.

### (4) Power Supply System Failure Simulation State—2

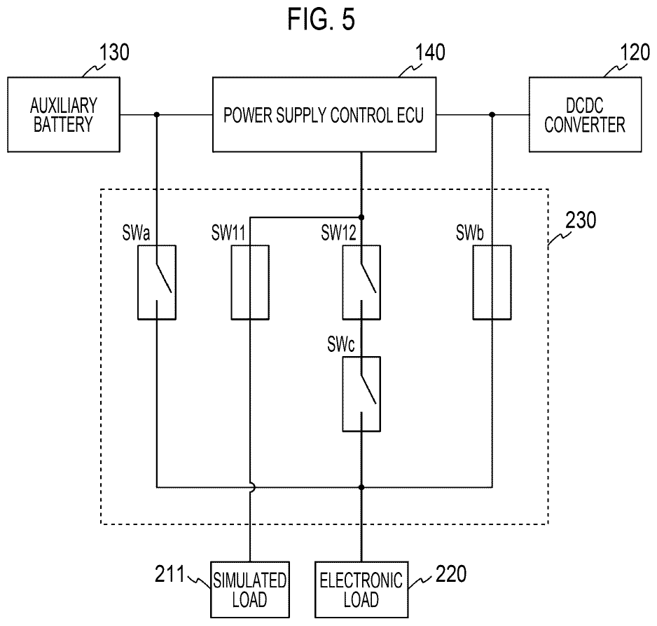

FIG. 5 is a diagram showing a connection state of switches SW11, SW12, SWa, SWb, and SWc in the simulation circuit 230 in a case where a state in which the DCDC converter 120 fails and an abnormality in which the supply of electric power from the DCDC converter 120 to the power supply control ECU 140 is lost is simulated.

In the power supply system failure simulation state-2, the switches SW12, SWa, SWc in the simulation circuit 230 are controlled to be in the disconnection state, and the switches SW11, SWb are controlled to be in the conduction state. With this control, all the power output from the DCDC converter 120 is absorbed by the electronic load 220, and the power supply source from the power supply control ECU 140 to the simulated load 211 is solely the auxiliary battery 130. As a result, the inspection unit 240 can safely and automatically inspect the operation (behavior) of the power supply control ECU 140 in the power supply system failure simulation state caused by the DCDC converter 120.

When the abnormality in which the auxiliary battery 130 and the DCDC converter 120 fail at the same time is simulated, the switch SW12 and the switch SWc in the simulation circuit 230 are controlled to the disconnection state. As a result, the switches SW11, SWa, and SWb may be controlled to be in a conduction state.

### Action and Effect

As described above, with the automatic inspection device 200 according to the embodiment of the present disclosure, the connection state of each of the switches in the simulation circuit 230 is appropriately controlled to simulate the disconnection state or the short-circuit state of the in-vehicle load, and further the failure state of the power supply system (auxiliary battery 130, DCDC converter 120). As a result, the operation (behavior) of the power supply control ECU 140 in the disconnection state of the in-vehicle load, the short-circuit state of the in-vehicle load, and the failure state of the power supply system can be inspected safely and automatically.

In addition, with the automatic inspection device 200 according to the embodiment of the present disclosure, a plurality of simulated loads 211, 212, 213 corresponding to a plurality of in-vehicle loads connected to the power supply control ECU 140 is prepared, and an input pattern of the vehicle state and an expected output pattern are prepared in advance. As a result, a large number of inspections can be automatically performed without changing the connection of the simulated loads 211, 212, 213 for each inspection.

Further, with the automatic inspection device 200 according to the embodiment of the present disclosure, the operation pattern of the electronic load 220 is changed. As a result, it is possible to confirm a transient state change from a normal state to an abnormal state in addition to a simple switching between normal and abnormal states of the simulated loads 211, 212, 213 by the simulation circuit 230.

Although the embodiment of the present disclosure has been described above, the present disclosure can be understood as a method executed by an automatic inspection device including a processor and a memory, a program of the method, a computer-readable non-transitory recording medium storing the program, a vehicle equipped with the automatic inspection device, or the like, in addition to the automatic inspection device described above.

The automatic inspection device of the present disclosure can be used in a case where an inspection of a power supply control ECU mounted on a vehicle is to be automatically performed.

What is claimed is:

1. An automatic inspection device configured to automatically perform inspection of a power supply control ECU, the automatic inspection device comprising:
a simulated load configured to simulate a control target;
an electronic load configured to consume electric power supplied from the power supply control ECU and a power supply system connected to the power supply control ECU that is able to supply electric power;
a simulation circuit disposed between the power supply control ECU and the simulated load, and between the power supply system and the electronic load; and
an inspection unit configured to inspect operation of the power supply control ECU in each of simulation states set by the simulation circuit,
wherein the simulation circuit
simulates a disconnection state of the simulated load by disconnecting a connection between the power supply system and the electronic load, a connection between the power supply control ECU and the electronic load, and a connection between the power supply control ECU and the simulated load,
simulates a short-circuit state of the simulated load by disconnecting the connection between the power supply system and the electronic load, and the connection between the power supply control ECU and the simulated load, and conducting the connection between the power supply control ECU and the electronic load, and
simulates a failure state of the power supply system by conducting the connection between the power supply control ECU and the simulated load, and the connection between the power supply system and the electronic load, and disconnecting the connection between the power supply control ECU and the electronic load.

2. The automatic inspection device according to claim 1, wherein:
a plurality of the simulated loads is provided; and
the simulation circuit individually switches connection states between the power supply control ECU and each of the simulated loads based on a pattern according to a desired inspection state.

3. The automatic inspection device according to claim 1, wherein the simulation circuit gradually changes magnitude of the electric power consumed by the electronic load to simulate a transient state change until the short-circuit state of the simulated load, and the failure state of the power supply system occur.
